(19) United States
(12) Patent Application Publication
(10) Pub. No.: US 2007/0145447 A1
(43) Pub. Date: Jun. 28, 2007

(54) Pixel and CMOS image sensor including the same

(75) Inventors: Yong Jei Lee, Seongnam-si (KR); Jung-Chak Ahn, Suwon-si (KR); Ju-Hyun Ko, Seongnam-si (KR); Sung-In Hwang, Yongin-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/645,171

(22) Filed: Dec. 26, 2006

(30) Foreign Application Priority Data
Dec. 28, 2005 (KR) 10-2005-0131888

(51) Int. Cl. H01L 31/113

(52) U.S. Cl. 257/292

(57) ABSTRACT

A pixel which may prevent the voltage of a floating diffusion region of the pixel from being outside a desired or predetermined driving voltage range by adjusting the equivalent capacitance of the floating diffusion region may be provided. The pixel may include a photodiode which may convert light energy into photocarriers, a transfer transistor which may transfer the photocarriers accumulated in the photodiode to a floating diffusion region, a select transistor which may transmit a data signal to the exterior in response to a selection control signal, the transmitted data signal having a voltage which may vary according to the voltage of the floating diffusion region, and/or at least one capacitor which may be connected between the floating diffusion region and the select transistor and which may adjust the equivalent capacitance of the floating diffusion region.

### PRIORITY STATEMENT

This application claims the benefit of priority to Korean Patent Application No. 10-2005-0131888, filed on Dec. 28, 2005, in the Korean Intellectual Property Office, the entire contents of which is incorporated herein in its entirety by reference.

### BACKGROUND

1. Field

Example embodiments relate to a pixel and/or a complementary metal-oxide semiconductor (CMOS) image sensor including the pixel, and for example, to a pixel and/or CMOS image sensor including the pixel which may adjust the equivalent capacitance of a floating diffusion region by disposing a capacitor between the floating diffusion region and/or may select a transmitter. Example embodiments relate to a method of operating the pixel and/or a CMOS image sensor including the pixel.

2. Description of Related Art

Image sensors may be classified into charge coupled device (CCD) image sensors or complementary metal-oxide semiconductor (CMOS) image sensors. CCD image sensors may include a photocarrier accumulation unit which photographs an external object, absorbs light, and/or accumulates photocarriers; a transmission unit which transmits the accumulated photocarriers; and/or an output unit which outputs the photocarriers transmitted by the transmission unit as electrical signals.

Photodiodes may be used as photocarrier accumulation units of CCD image sensors. Photocarriers accumulated in a photodiode may be transmitted to an external device via a transmission unit and/or an output unit of a CCD image sensor. When the detection of an electrical signal by the CCD image sensor is concluded, the electric charges accumulated in the photodiode must be discharged for a subsequent image sensing operation. The discharging may be referred to as a reset operation.

Driving CCD image sensors, which may operate in the aforementioned manner, may be more complicated than driving CMOS image sensors, and CCD image sensors may consume more power than CMOS image sensors. Accordingly, CMOS image sensors, which may consume less power and/or may offer a higher integration density than CCD image sensors, have become more widely used.

FIG. 1 is a circuit diagram of a pixel 100 of a conventional CMOS image sensor. Referring to FIG. 1, the pixel 100 may include a photodiode PD which may generate photocarriers by receiving light, and/or a plurality of transistors, including a transfer transistor T1, a reset transistor T2, a drive transistor T3, and/or a select transistor T4.

The transfer transistor T1 may transfer photocarriers accumulated in the photodiode PD to a floating diffusion region FD in response to a transmission control signal Tx. The reset transistor T2 may reset the electrical potential of the floating diffusion region FD to a power supply voltage VDD in response to a reset signal Rx, thereby discharging photocarriers present in the floating diffusion region FD.

The drive transistor T3 may serve as a source follower-buffer amplifier. The select transistor T4 may perform an addressing operation. For example, the select transistor T4 may be switched on in response to a selection control signal Sx and may transmit an output signal of the pixel 100 via an output port OUT. A load transistor T5 may be connected to the pixel 100. The load transistor T5 may read the voltage of the output signal of the pixel 100 under the control of a desired or predetermined load control signal LOAD.

The operation of the pixel 100 will now be described. The transfer transistor T1 and/or the reset transistor T2 may be turned on, thereby resetting the pixel 100. The photodiode PD may begin to be depleted and may be charged with carriers, and the floating diffusion region FD may be charged in accordance with a supply voltage VDD.

The transfer transistor T1 may be turned off, the select transistor T4 may be turned on, and/or the reset transistor T2 may be turned off. A first output voltage V1, which may be output from the output port OUT of the pixel 100, may be read out and stored in a buffer (not shown). The transfer transistor T1 may be turned on, thereby transferring photocarriers which may be accumulated in the photodiode PD and have a total electric charge that may depend on the intensity of light incident on the photodiode PD to the floating diffusion region FD. A second output voltage V2, which may be output from the output port OUT, may be read out. A difference between the first output voltage V1 and the second output voltage V2 may be calculated, and analog data obtained through the calculation may be converted into digital data.

When the size of the photodiode PD is reduced, the effective area of the photodiode PD for accumulating photocarriers may decrease. However, there may still be a clear limit in increasing the effective area of the photodiode PD as the integration density of electronic devices may increase. When the effective area of the photodiode PD is increased, the area of the floating diffusion region FD, which may be formed in an active region, may decrease.

If the area of the floating diffusion region FD decreases, the intrinsic capacitance Cfd of the floating diffusion region FD may decrease, and conversion gain, which may be defined as 1/Cfd, may increase. For example, when photocarriers are transferred to the floating diffusion region FD, the conversion gain may increase, and the degree by which the voltage of the floating diffusion region FD drops may increase.

If the degree by which the voltage of the floating diffusion region FD drops increases to the extent that the voltage of the floating diffusion region may be outside a certain driving voltage range, photocarriers may backflow from the floating diffusion region FD to the photodiode PD. Conventional CMOS image sensors may not, however, address the problem of an increasing conversion gain value.

### SUMMARY

Example embodiments may provide a pixel and/or a complementary metal-oxide semiconductor (CMOS) image sensor including the pixel which may address the problem of backflow of photocarriers caused due to an increase in conversion gain. Example embodiments may provide a method of operating the pixel.

According to an example embodiment, there may be provided a pixel. The pixel may include a photodiode which may convert light energy into photocarriers, a transfer transistor which may transfer the photocarriers accumulated in the photodiode to a floating diffusion region, a select transistor which may transmit a data signal to the exterior in response to a selection control signal, the externally transmitted data signal having a voltage which may vary according to a voltage of the floating diffusion region, and/or at least one capacitor which may be connected between the floating diffusion region and the select transistor and which may adjust an equivalent capacitance of the floating diffusion region.

According to an example embodiment, the first electrode of the capacitor may be connected to the floating diffusion region, and the second electrode of the capacitor may be connected to a gate of the select transistor.

According to an example embodiment, the capacitor may be connected in parallel to a capacitance component of the floating diffusion region.

According to an example embodiment, the equivalent capacitance of the floating diffusion region may be adjusted such that the voltage of the floating diffusion region may remain higher than a voltage of the photodiode when all the photocarriers accumulated in the photodiode are transferred to the floating diffusion region.

According to an example embodiment, the selection control signal may be a voltage signal which may be toggled between a power supply voltage and a ground voltage, wherein the power supply voltage and the ground voltage may be input to the pixel.

According to an example embodiment, the capacitor may have a polysilicon-insulator-polysilicon (PIP) structure.

According to an example embodiment, the capacitor may have a metal-insulator-metal (MIM) structure.

According to an example embodiment, a pixel may include a photodiode which may convert light energy into photocarriers, a transfer transistor which may transfer the photocarriers accumulated in the photodiode to a floating diffusion region, a select transistor which may transmit a data signal externally in response to a selection control signal, the externally transmitted data signal having a voltage which varies according to the voltage of the floating diffusion region, and/or at least one capacitor which may be connected in parallel to a capacitance component of the floating diffusion region and which may increase the equivalent capacitance of the floating diffusion region.

According to an example embodiment, a complementary metal-oxide semiconductor (CMOS) may include at least one of the pixel.

According to an example embodiment, a method of operating a pixel may include setting a selection control signal applied to a select transistor to a logic low voltage and a reset signal applied to a reset transistor to a logic high voltage to reset a voltage of a floating diffusion region by increasing the voltage of the floating diffusion region to a power supply voltage, setting the selection control signal to a logic high voltage and the reset signal to a logic low voltage to stop the resetting of the floating diffusion region, setting a transmission control signal applied to a transfer transistor to a logic high voltage so that photocarriers accumulated in a photodiode are transferred to the floating diffusion region, setting the transmission control signal to a logic low voltage, and/or altering the voltage of the floating diffusion region by adjusting a capacitance between the floating diffusion region and the select transistor.

### BRIEF DESCRIPTION OF THE DRAWINGS

The above and/or other aspects and advantages will become more apparent and more readily appreciated from the following detailed description of example embodiments taken in conjunction with the accompanying drawings of which:

FIG. 1 is an example circuit diagram of a pixel of a conventional complementary metal-oxide semiconductor (CMOS) image sensor;

FIG. 2 is an example circuit diagram of a pixel of a CMOS image sensor according to an example embodiment;

FIG. 3 is an example timing diagram illustrating the waveforms of control signals used to drive the pixel illustrated in FIG. 2 and the waveform of a voltage output from the pixel illustrated in FIG. 2; and

FIG. 4 is an example graph of the output voltage of a pixel of a CMOS image sensor according to an example embodiment according to the equivalent capacitance of a floating diffusion region of the pixel.

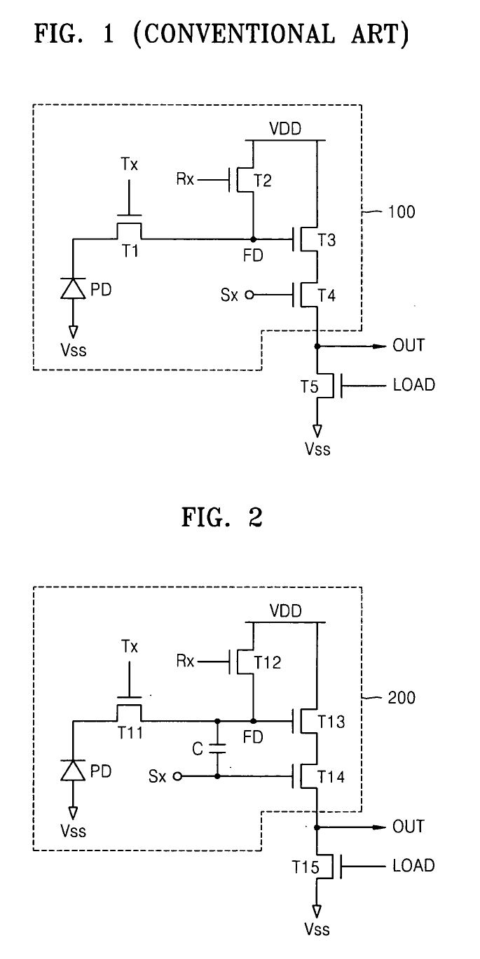

### DETAILED DESCRIPTION OF EXAMPLE EMBODIMENTS

Example embodiments will now be described more fully with reference to the accompanying drawings. Embodiments may, however, be in many different forms and should not be construed as being limited to the example embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when a component is referred to as being “on,” “connected to” or “coupled to” another component, it can be directly on, connected to or coupled to the other component or intervening components may be present. In contrast, when a component is referred to as being “directly on,” “directly connected to” or “directly coupled to” another component, there are no intervening components present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one component or feature's relationship to another component(s) or feature(s) as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made to example embodiments, which are illustrated in the accompanying drawings, wherein like reference numerals refer to the like components throughout.

FIG. 2 is an example circuit diagram of a pixel 200 of a complementary metal-oxide semiconductor (CMOS) image sensor according to an example embodiment. Referring to FIG. 2, the pixel 200 may include a photodiode PD which may generate photocarriers by receiving light, and/or a plurality of transistors, including a transfer transistor T11, a reset transistor T12, a drive transistor T13, and/or a select transistor T14.

A first electrode of the transfer transistor T11 may be connected to a photodiode PD, and a second electrode of the transfer transistor T11 may be connected to a floating diffusion region FD. The transfer transistor T11 may transfer photocarriers generated in the photodiode PD to the floating diffusion region FD in response to a transmission control signal Tx.

A first electrode of the reset transistor T12 may be connected to a power supply voltage VDD, and a second electrode of the reset transistor T12 may be connected to the floating diffusion region FD. The reset transistor T12 may reset the electric potential of the floating diffusion region Fd to the power supply voltage VDD in response to a reset signal Rx, thereby discharging the photocarriers accumulated in the floating diffusion region FD.

A first electrode of the drive transistor T13 may be connected to the power supply voltage VDD. The drive transistor T13 may serve as a source follower-buffer amplifier. A first electrode of the select transistor T14 may be connected to a second electrode of the drive transistor T13, and a second electrode of the select transistor T14 may be connected to an output port OUT. The select transistor T14 may be used in an addressing operation. The select transistor T14 may be switched on in response to a selection control signal Sx and may transmit a data signal to the output port OUT.

A load transistor T15, which may be located outside the pixel 200, may be connected to the pixel 200. The load transistor T15 may read the voltage of a signal output from the output port OUT. A first electrode of the load transistor T15 may be connected to the output port OUT, and a second electrode of the load transistor T15 may be connected to a desired or predetermined voltage Vss. The desired or predetermined voltage Vss may be a ground voltage.

As described above, as the integration density of devices increases, the size of pixels of a CMOS image sensor may decrease. However, there may be a clear limit in reducing the size of the photodiode PD because of the need to increase the sensitivity of the photodiode PD. As the effective area of the photodiode PD increases, the area of the floating diffusion region FD, which may be formed in an active region, may decrease.

As the area of the floating diffusion region FD decreases, the intrinsic capacitance Cfd of the floating diffusion region FD may decrease, and the conversion gain, which may be defined as 1/Cfd, may increase. Accordingly, when transferring a single photocarrier to the floating diffusion region FD, the magnitude of the drop in voltage of the floating diffusion region FD (for example, e/Cfd where e indicates the electric charge of a photocarrier) may increase because of the increase in conversion gain.

The first electrode of the photodiode PD which may be connected to the floating diffusion region FD may have a voltage of 1.2 V, and the power supply voltage VDD may be 2.8 V. If all photocarriers stored in the photodiode PD are transferred to the floating diffusion region FD, the voltage of the floating diffusion region FD may be between a range of 1.2 V to 2.8 V. If, for example, the maximum number of photocarriers that may be accumulated in the photodiode PD is 10,000 and the voltage of the floating diffusion region FD drops by 40-90 μV for the transmission of each photocarrier, the voltage of the floating diffusion region FD may drop by 0.4-0.9 V when all the photocarriers accumulated in the photodiode PD are transmitted to the floating diffusion region FD, and the voltage of the floating diffusion region FD may drop from the reset value of 2.8 V to a range of 2.1-2.4 V. Accordingly, the voltage of the floating diffusion region FD may be within the aforementioned range of 1.2-2.8 V. However, if, due to a decreasing capacitance of the floating diffusion region FD, the voltage of the floating diffusion region FD drops by 200 μV for the transmission of each photocarrier, the voltage of the floating diffusion region FD may drop by 2 V when all the photocarriers accumulated in the photodiode PD are transmitted to the floating diffusion region FD, and the voltage of the floating diffusion region FD may drop from the reset value of 2.8 V to 0.8 V. Accordingly, the voltage of the floating diffusion region FD may be outside the aforementioned range of 1.2-2.8 V. For example, the voltage of the photodiode PD may be higher than the voltage of the floating diffusion region FD. Accordingly, photocarriers may backflow from the floating diffusion region FD to the photodiode PD.

In order to address the problem of backflowing photocarriers, the pixel 200 may include at least one capacitor c, which may be connected between the floating diffusion region FD and the select transistor T14, and may adjust the equivalent capacitance of the floating diffusion region FD. When the effective area of the floating diffusion region FD is reduced, the equivalent capacitance of the floating diffusion region FD may be increased.

A first electrode of the capacitor C may be connected to the floating diffusion region FD and a second electrode of the capacitor C may be connected to the gate of the select transistor T14. Accordingly, a selection control signal Sx which may be used to control the turning on or off of the select transistor T14 may be applied to the second electrode of the capacitor C.

The capacitor C may be connected between the floating diffusion region FD and the select transistor T14 such that the capacitor C is connected in parallel to a capacitance component of the floating diffusion region FD. The equivalent capacitance (Ce) of the floating diffusion region FD may be equal to the sum of the intrinsic capacitance Cfd of the floating diffusion region FD and the capacitance Cc of the capacitor C. Accordingly, the equivalent capacitance (Ce) of the floating diffusion region FD may be increased.

In order to store photocarriers transferred from the photodiode PD to the capacitor C, a desired or predetermined voltage must be applied to the second electrode of the capacitor C. For example, the selection control signal Sx may be applied to the second electrode of the capacitor C. The selection control signal Sx may transit from logic low to logic high within a desired or predetermined time period. The voltage of the logic low state of the selection control signal Sx may be the same as the voltage Vss, which may be a ground voltage. The voltage of the logic high state of the selection control signal Sx may be the same as the power supply voltage VDD illustrated in FIG. 2.

The selection control signal Sx may have a regulated voltage. A signal output from the output port OUT when the selection control signal Sx applied to the second electrode of the capacitor C has a uniform voltage is more stable than a signal output to the output port OUT when the power supply voltage VDD is applied to the second electrode of the capacitor C. For example, if an irregular voltage is applied to the second electrode of the capacitor C, the voltage of the floating diffusion region FD may become irregular and fluctuate proportionally to the equivalent capacitance (Ce) of the floating diffusion region FD.

The capacitor C may have a polysilicon-insulator-polysilicon (PIP) structure or a metal-insulator-metal (MIM) structure, however example embodiments may not be restricted to thereto.

The operation of the pixel 200 of the CMOS image sensor illustrated in FIG. 2 will now be described.

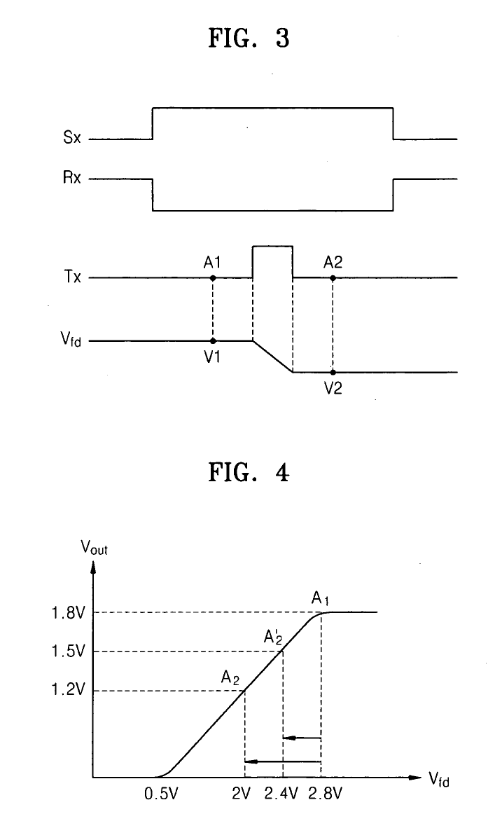

FIG. 3 is an example timing diagram illustrating the waveforms of control signals used to drive the pixel 200 and the waveform of a voltage output from the pixel 200 according to an example embodiment. Referring to FIG. 3, the select control signal Sx may control the select transistor T14, a reset signal Rx may control the reset transistor T12, a transmission control signal Tx may control the transfer transistor T11, and/or a voltage Vfd may be the voltage of the floating diffusion region FD of FIG. 2.

When the selection control signal Sx is logic low and the reset signal Rx is logic high, the floating diffusion region FD may be reset. The voltage of the floating diffusion region FD may increase to the power supply voltage VDD.

When the selection control signal Sx is toggled to logic high and the reset signal Rx is toggled to logic low, the resetting of the floating diffusion region FD may be stopped, and data may be read out from the output port OUT. Because the transmission control signal Tx has not yet been toggled to logic high, photocarriers accumulated in the photodiode PD may not be transferred to the floating diffusion region FD. Accordingly, a voltage V1 of the floating diffusion region at a time A1 may be equivalent to the power supply voltage VDD.

When the transmission control signal Tx is toggled to logic high, the transfer transistor T11 may be turned on. The photocarriers accumulated in the photodiode PD may be transferred to the floating diffusion region FD. When the transmission control signal Tx is maintained at logic high, all the photocarriers accumulated in the photodiode PD may be transferred to the floating diffusion region FD so that the voltage of the floating diffusion region FD may gradually decrease as shown in FIG. 3.

When the transmission control signal Tx is toggled back to logic low, the floating diffusion region may be maintained at a lower voltage. The voltage V2 of the floating diffusion region FD at a time A2 may be altered by adjusting the capacitance Cc of the capacitor C. Accordingly, the equivalent capacitance (Ce) and/or the conversion gain (1/Ce) of the floating diffusion region FD may be changed.

For example, the equivalent capacitance (Ce) of the floating diffusion region FD may be adjusted to be equal to 1×C or 2×C, where C may be an exemplary capacitance, by adjusting the capacitance Cc of the capacitor C.

When the power supply voltage VDD is 2.8 V and the equivalent capacitance (Ce) of the floating diffusion region FD is 1×C the voltage of the floating diffusion region FD may drop by 0.8 V when a desired or predetermined number of photocarriers may be transferred from the photodiode PD to the floating diffusion region FD, so that the voltage of the floating diffusion region FD may drop from 2.8 V to 2 V.

When the equivalent capacitance (Ce) of the floating diffusion region FD is 2×C, the conversion gain (1/Ce) may be half of the conversion gain when the equivalent capacitance (Ce) of the floating diffusion region FD is 1×C. Accordingly, when the equivalent capacitance (Ce) of the floating diffusion region FD is 2×C and the desired or predetermined number of photocarriers are transferred from the photodiode PD to the floating diffusion region FD, the voltage of the floating diffusion region FD may drop by half as much as when the equivalent capacitance (Ce) of the floating diffusion region FD is 1×C. For example, the voltage of the floating diffusion region FD may drop by 0.4 V, so that the voltage of the floating diffusion region FD may drop from 2.8 V to 2.4 V.

When the conversion gain may be increased due to a reduction in the floating diffusion region FD and the associated reduction in intrinsic capacitance Cfd, the capacitance Cc of the capacitor C may be adjusted according to the change in conversion gain, thereby maintaining the voltage of the floating diffusion region FD within a desired or predetermined driving voltage range.

FIG. 4 is an example graph of the output voltage of a pixel of a CMOS image sensor according to an example embodiment in relation to the capacitance of a floating diffusion region FD of the pixel. Referring to FIG. 4, reference character Vfd may represent the voltage of the floating diffusion region FD, and reference character Vout may represent the voltage of the data signal output via the output port OUT of the pixel.

At time A1, the voltage Vfd of the floating diffusion region FD may be equal to the power supply voltage VDD, for example, 2.8 V. Due to the operation of the drive transistor T13, which may serve as a source follower, the voltage of the data signal output from the output port OUT may be 1.8 V.

When photocarriers are transferred from the photodiode PD to the floating diffusion region FD, the voltage Vfd of the floating diffusion region FD may decrease to the voltage V2 at time A2. Reference character A2 corresponds to the case when the equivalent capacitance (Ce) of the floating diffusion region FD is 1×C, and reference character A′2 corresponds to the case when the equivalent capacitance (Ce) of the floating diffusion region FD is 2×C. For example, when the same number of photocarriers are transferred from the photodiode PD to the floating diffusion region FD, the conversion gain of the floating diffusion region FD when the equivalent capacitance (Ce) of the floating diffusion region FD is 2×C may be only half of the conversion gain of the floating diffusion region FD when the equivalent capacitance (Ce) of the floating diffusion region FD is 1×C. Accordingly, the voltage drop of the floating diffusion region FD when the equivalent capacitance of the floating diffusion region FD is 2×C may be only half of the voltage drop of the floating diffusion region FD when the equivalent capacitance of the floating diffusion region FD is 1×C. If the voltage Vfd of the floating diffusion region FD is 2.4 V, for example as indicated by A′2, a voltage of 1.5 V may be output from the output port OUT. If the voltage Vfd of the floating diffusion region is 2.0V, for example as indicated by A2, a voltage of 1.2 V may be output from the output port OUT.

It may be possible to prevent backflow of photocarriers when the conversion gain of the pixel is increased by adjusting the equivalent capacitance of a floating diffusion region of each pixel of a CMOS image sensor. It may be possible to more precisely photograph images.

Although example embodiments have been shown and described in this specification and figures, it would be appreciated by those skilled in the art that changes may be made to the illustrated and/or described example embodiments without departing from their principles and spirit, the scope of which is defined by the claims and their equivalents.

What is claimed is:

1. A pixel comprising:
a photodiode which converts light energy into photocarriers;
a transfer transistor which transfers the photocarriers accumulated in the photodiode to a floating diffusion region;
a select transistor which transmits a data signal externally in response to a selection control signal, the externally transmitted data signal having a voltage which varies according to the voltage of the floating diffusion region; and
at least one capacitor which is connected between the floating diffusion region and the select transistor and which adjusts an equivalent capacitance of the floating diffusion region.

2. The pixel of claim 1, wherein a first electrode of the at least one capacitor is connected to the floating diffusion region, and a second electrode of the at least one capacitor is connected to a gate of the select transistor.

3. The pixel of claim 2, wherein the at least one capacitor is connected in parallel to a capacitance component of the floating diffusion region.

4. The pixel of claim 3, wherein the equivalent capacitance of the floating diffusion region is adjusted such that the voltage of the floating diffusion region remains higher than a voltage of the photodiode when all the photocarriers accumulated in the photodiode are transferred to the floating diffusion region.

5. The pixel of claim 1, wherein the selection control signal is a voltage signal which is toggled between a power supply voltage and a ground voltage, wherein the power supply voltage and the ground voltage are input to the pixel.

6. The pixel of claim 1, wherein the at least one capacitor includes a polysilicon-insulator-polysilicon (PIP) structure.

7. The pixel of claim 1, wherein the at least one capacitor includes a metal-insulator-metal (MIM) structure.

8. The pixel of claim 3, wherein the at least one at least one capacitor increases the equivalent capacitance of the floating diffusion region.

9. The pixel of claim 8, wherein the at least one capacitor is connected between the floating diffusion region and the select transistor.

10. The pixel of claim 8, wherein the first electrode of the at least one capacitor is connected to the floating diffusion region, and the second electrode of the at least one capacitor is connected to a gate of the select transistor.

11. The pixel of claim 10, wherein the equivalent capacitance of the floating diffusion region is adjusted such that the voltage of the floating diffusion region remains higher than a voltage of the photodiode when all the photocarriers accumulated in the photodiode are transferred to the floating diffusion region.

12. The pixel of claim 8, wherein the selection control signal is a voltage signal which is toggled between a power supply voltage and a ground voltage, wherein the power supply voltage and the ground voltage are input to the pixel.

13. The pixel of claim 8, wherein the at least one capacitor includes a polysilicon-insulator-polysilicon (PIP) structure.

14. The pixel of claim 8, wherein the at least one capacitor includes a metal-insulator-metal (MIM) structure.

15. A complementary metal-oxide semiconductor (CMOS) image sensor comprising:
at least one of the pixels of claim 1.

16. The complementary metal-oxide semiconductor (CMOS) image sensor of claim 15, wherein the selection control signal in each pixel is a voltage signal which is toggled between a power supply voltage and a ground voltage, wherein the power supply voltage and the ground voltage are input to each pixel of the CMOS image sensor.

17. The complementary metal-oxide semiconductor (CMOS) image sensor of claim 15, wherein the at least one capacitor of each at least one pixel is connected in parallel to a capacitance component of the floating diffusion region of each at least one pixel,
wherein the at least one capacitor of each at least one pixel increases the equivalent capacitance of the floating diffusion region, and
wherein the selection control signal in each pixel is a voltage signal which is toggled between a power supply voltage and a ground voltage, wherein the power supply voltage and the ground voltage are input to each pixel of the CMOS image sensor.

18. A method of operating a pixel comprising:
setting a selection control signal applied to a select transistor to a logic low voltage and a reset signal applied to a reset transistor to a logic high voltage to reset a voltage of a floating diffusion region by increasing the voltage of the floating diffusion region to a power supply voltage;
setting the selection control signal to a logic high voltage and the reset signal to a logic low voltage to stop the resetting of the floating diffusion region;
setting a transmission control signal applied to a transfer transistor to a logic high voltage so that photocarriers accumulated in a photodiode are transferred to the floating diffusion region;
setting the transmission control signal to a logic low voltage; and
altering the voltage of the floating diffusion region by adjusting a capacitance between the floating diffusion region and the select transistor.

19. The method of claim 18, wherein adjusting the capacitance includes adjusting a capacitance of at least one capacitor is connected in parallel to a capacitance component of the floating diffusion region.

20. The method of claim 19, further comprising:
increasing the capacitance of the at least one capacitor.
